(19) United States
(12) Patent Application Publication
(10) Pub. No.: US 2026/0186027 A1
(43) Pub. Date: Jul. 2, 2026

(54) SEMICONDUCTOR TESTING DEVICE AND INSPECTION SYSTEM

(71) Applicant: KABUSHIKI KAISHA NIHON MICRONICS, Tokyo (JP)

(72) Inventors: Hideki IKEUCHI, Musashino-shi (JP); Furawa ODAGIRI, Musashino-shi (JP); Shoujirou YAHATA, Musashino-shi (JP)

(73) Assignee: KABUSHIKI KAISHA NIHON MICRONICS, Tokyo (JP)

(21) Appl. No.: 19/411,703

(22) Filed: Dec. 8, 2025

(30) Foreign Application Priority Data
Dec. 26, 2024 (JP) 2024-230894

(51) Int. Cl. G01R 1/073

(52) U.S. Cl. CPC G01R 1/07378

(57) ABSTRACT

A semiconductor testing device that includes an under base unit, an under base plate, a floating plate that is connected to an under base unit connector, and is movable on the under base plate towards a mounting direction of a circuit board connector with respect to the under base unit connector, and a coil spring that is elastically deformable, and is interposed between the under base plate and the floating plate in a the mounting direction.

### TECHNICAL FIELD

The present invention relates to a semiconductor testing device, and an inspection system. Priority is claimed on Japanese Patent Application No. 2024-230894, filed on Dec. 26, 2024, the content of which is incorporated herein by reference.

### BACKGROUND ART

For example, a wafer test system that includes a test head and a prober is disclosed in Patent Document 1 (Japanese Unexamined Patent Application, First Publication No. 2004-172551). The wafer test system disclosed in Patent Document 1 includes the test head, and a test head support/reduction device.

### SUMMARY OF THE INVENTION

A wafer system such as the inspection system disclosed in Patent Document 1 includes a semiconductor testing device, such as the test head of Patent Document 1, which conducts inspection of a semiconductor integrated circuit. The semiconductor testing device includes a performance board unit and a plurality of units such as a circuit board units. Such units include connectors that make connection with one another possible, and the connectors are electrically connected to one another. Due to the above however, there are cases where connectors are not sufficiently fitted to one another due to dimensional errors or the like.

The present invention has been made in view of the above problem, and an object thereof is to insure reliable connectivity between connectors, for connectors used to connect a plurality of units included in a semiconductor testing device.

A semiconductor testing device according to an embodiment of the present invention includes a first unit that includes a first connector, and a second unit that includes a second connector which is connectable to the first connector. The first unit includes a base, a moving part that contacts the first connector and is movable relative to the base in a mounting direction of the second connector with respect to the first connector, and an elastically deformable part that is elastically deformable and interposes between the base and the moving part in the mounting direction.

An inspection system according to an embodiment of the present invention includes the aforementioned semiconductor testing device, and a test object transport device that transports a test object which has a semiconductor integrated circuit provided thereon, and connects the test object to the semiconductor testing device.

According to an embodiment of the present invention, it is possible to more assuredly have connectors connect to one another in a semiconductor testing device which includes a plurality of units that are connected using connectors.

### BRIEF DESCRIPTION OF DRAWINGS

FIG. 1 A schematic diagram showing an outline of an inspection system in an embodiment of the present invention.

FIG. 2 A perspective view of a tester in an embodiment of the present invention.

FIG. 3 An exploded perspective view of the tester in an embodiment of the present invention.

FIG. 4 A schematic exploded perspective view of a main body in an embodiment of the present invention.

FIG. 5 A schematic perspective view of a circuit board unit in an embodiment of the present invention.

FIG. 6 A schematic exploded perspective view of a performance board unit in an embodiment of the present invention.

FIG. 7 A schematic exploded perspective view of an under base unit in an embodiment of the present invention.

FIG. 8 A schematic exploded perspective view of the under base unit as seen diagonally from below.

FIG. 9 A cross-sectional view taken from A-A of FIG. 8.

FIG. 10 A cross-sectional view taken from B-B of FIG. 8.

FIG. 11 A schematic exploded cross-sectional view which shows a stud bolt of the under base unit in an embodiment of the present invention.

FIG. 12 A schematic exploded cross-sectional view which shows the stud bolt of the under base unit in an embodiment of the present invention.

FIG. 13 A schematic exploded cross-sectional view which shows the stud bolt of the under base unit in an embodiment of the present invention.

FIG. 14 A schematic exploded cross-sectional view that shows a connector fixing pin in an embodiment of the present invention.

FIG. 15 A schematic exploded cross-sectional view that shows the connector fixing pin in an embodiment of the present invention.

FIG. 16 A schematic exploded cross-sectional view that shows the connector fixing pin in an embodiment of the present invention.

### DESCRIPTION OF EMBODIMENTS

Hereinafter, an embodiment of a semiconductor testing device and an inspection system according to the present invention is described with reference to the drawings.

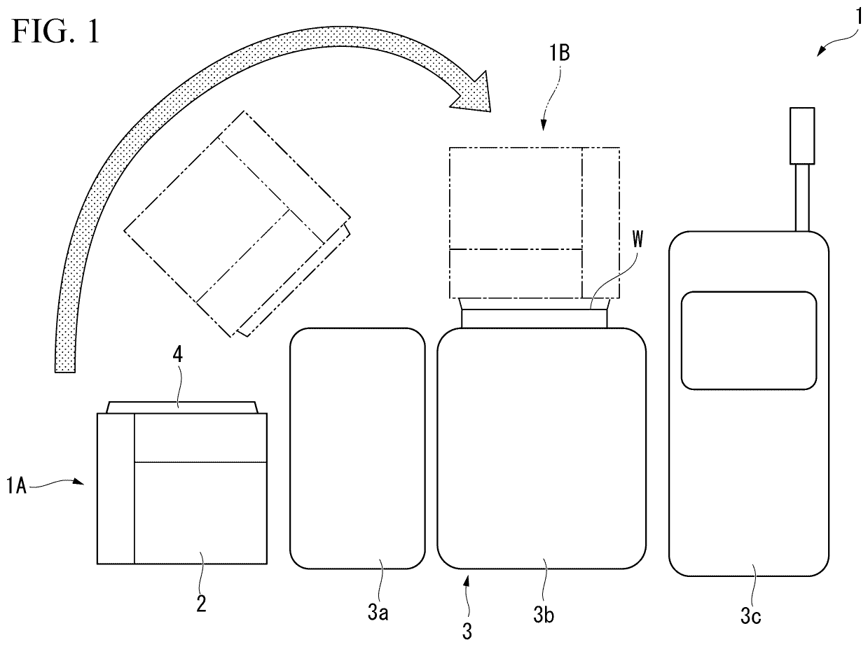

FIG. 1 is a schematic diagram showing an outline of an inspection system 1. The inspection system 1 of the present embodiment conducts inspection of electrical characteristics of a semiconductor integrated circuit, where a wafer W having a semiconductor circuit is provided as a test object. As shown in FIG. 1, the inspection system 1 includes a tester 2 (semiconductor testing device), and a prober 3 (handler; test object transport device). The aforementioned inspection system 1 inspects electrical characteristics of each semiconductor circuit before a plurality of semiconductor circuits which are formed on the wafer W are individually diced into chips.

A probe card 4 is installed in the tester 2. The probe card 4 includes a plurality of probes. The prober 3 causes the probe card 4, having the plurality of probes provided thereon, to contact pads of the plurality of the semiconductor circuits that are formed on the wafer W. The prober 3 includes a tester transport device 3a, a stage device 3b, and a wafer transport device 3c.

The tester transport device 3a includes a transport mechanism that is not shown on the drawings, and moves the tester 2 from the standby position 1A to the inspection location 1B. The stage device 3b supports the wafer W, and aligns a location of the tester 2 and the wafer W located at the inspection location 1B. The stage device 3b is movable in a planar direction along a horizontal plane, and in a vertical direction that is perpendicular to the horizontal plane. The stage device 3b is rotatable around the vertical axis in the θ-direction. The wafer transport device 3c transports the wafer W on the stage device 3b.

When conducting inspection, the stage device 3b moves the wafer W, and causes the pads of the plurality of semiconductors, which are formed on the wafer W to contact tips of the plurality of probes of the probe card 4 provided in the tester 2 which is located in the inspection location 1B. In such state, the tester 2 inputs a test signal simultaneously to each semiconductor circuit via each of the plurality of probes, and by receiving the input signal from each semiconductor circuit, inspects of each semiconductor circuits.

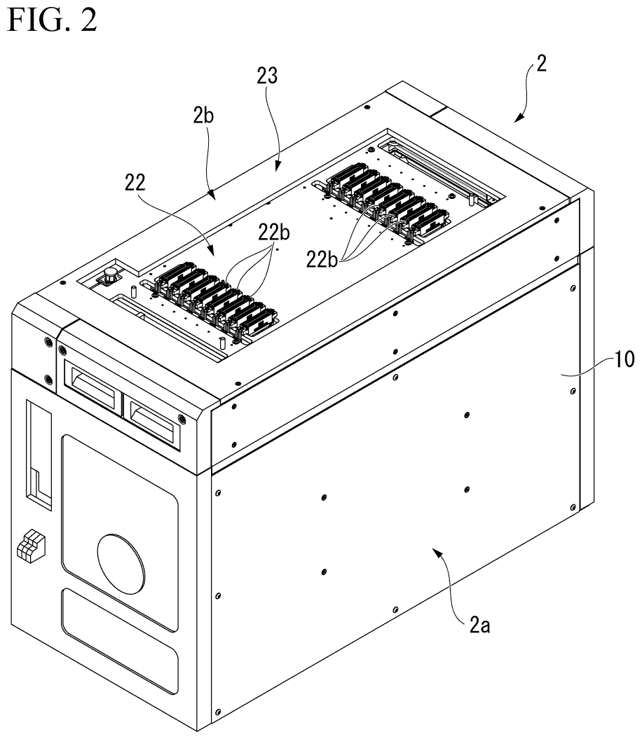

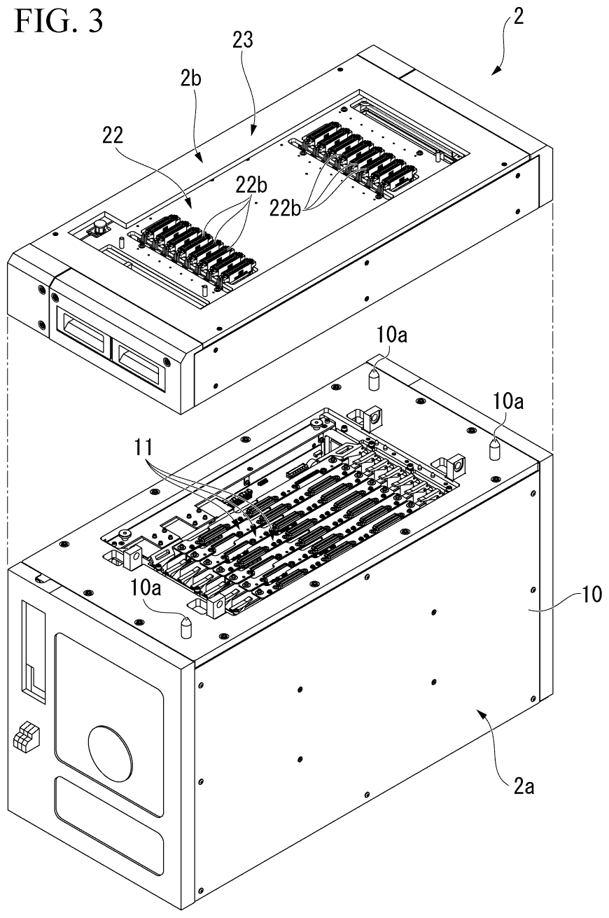

FIG. 2 is a perspective view of a tester 2. Both FIG. 2 and FIG. 3 are exploded views. As can be seen from such drawings, the tester 2 includes a main body 2a and a performance board unit 2b. Both FIG. 2 and FIG. 3 show the tester 2 in a standby position 1A. The tester 2 in the standby position 1A is oriented so as to face above on the side the probe card 4 is installed on. In the explanations hereinafter, explanations are carried out based on a direction where the tester 2 is in a state of being disposed in the standby position 1A.

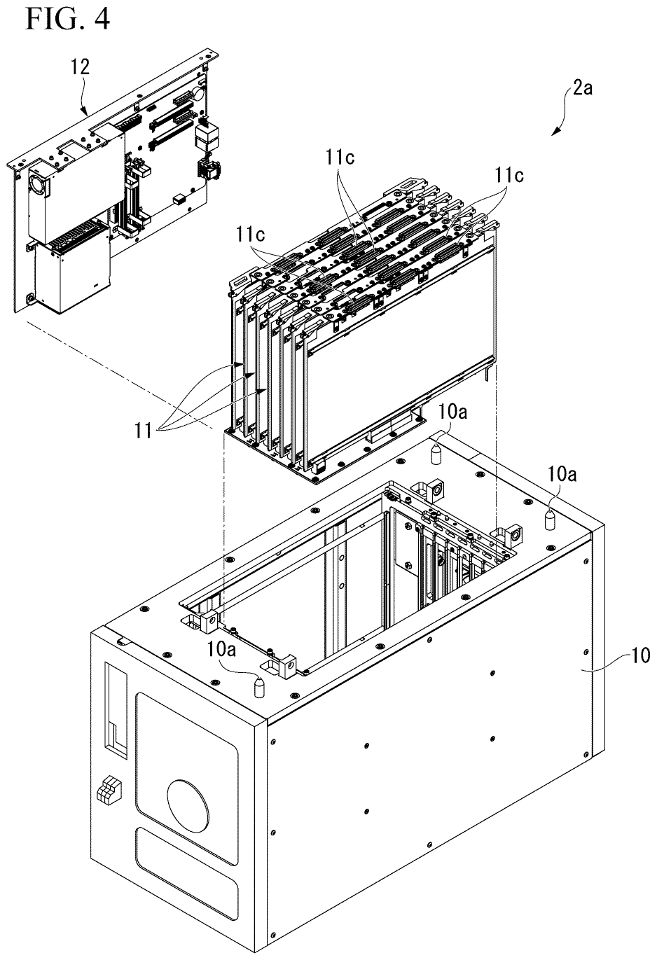

The main body 2a is a unit that conducts signal processing for testing of the wafer W, and detachably supports the performance board unit 2b. FIG. 4 is a schematic exploded perspective view of the main body 2a. As shown in FIG. 4, the main body 2a includes a main body housing 10, a plurality of circuit board units 11 (second units), and a control processing unit 12.

The main body housing 10 is a housing that accommodates the circuit board unit 11 and the control processing unit 12. In the present embodiment, the main body housing 10 is a box that is formed so as to open from above. A plurality of slots into which the circuit board units 11 are detachably inserted are provided inside the main body housing 10. By inserting each of the circuit board units 11 into the aforementioned slots, the circuit board units 11 are accommodated inside the main body housing 10. A plurality of location pins 10a for the performance board unit are provided on a top surface of the main body housing 10. The plurality of location pins 10a for the performance board unit conduct positioning of the performance board unit 2b in a case where the performance board unit 2b is mounted on the main body 2a from above.

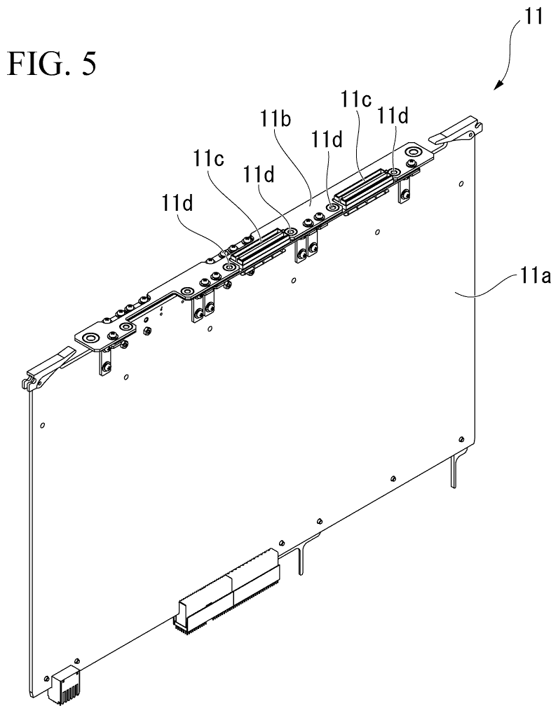

The circuit board unit 11 is a circuit board onto which electronic components that conduct processing of various signals are mounted, and is exchangeable in response to the type or the like of the wafer W to be tested. FIG. 5 is a schematic perspective view of the circuit board unit 11. As shown in FIG. 5, the circuit board unit 11 includes a circuit board main body 11a, an upper plate 11b, and a circuit board connector 11c (second connector).

The circuit board main body 11a is an electronic circuit board, and is accommodated in the main body housing 10 so as to have front-rear surface thereof face the horizontal direction. As shown in FIG. 4, the plurality of the circuit board units 11 are arranged so as to have the front-rear surfaces of the circuit board main bodies 11a face one another. In the present embodiment, the main body housing 10 is formed so as to be a rectangle in a planar view thereof. Each circuit board main body 11a is disposed along the longer end of the main body housing 10 in planar view.

The upper plate 11b is a band plate member connected to a top end of each circuit board main body 11a. The upper plate 11b extends along the longer side of the main body housing 10, as seen in planar view. Each upper plate 11b is fixed to each circuit board connector 11c. The upper plate 11b may be formed of one band-like plate material, and may be formed of a plurality of plate materials that are stacked on one another.

The upper plate 11b includes an insertion hole 11d that is provided so as to have a connector fixing pin 35, which is included in the performance board unit 2b and is to be mentioned later on, insertable from above (refer to FIG. 10). Two insertion holes 11d are provided for fixing positions of each one of the circuit board connectors 11c. The insertion holes 11d are disposed so as to sandwich each circuit board connector 11c inbetween. In other words, for every fixing position of the circuit board connector 11c, two of the insertion holes 11d are provided with respect to the upper plate 11b.

The circuit board connectors 11c are provided on each circuit board main bodies 11a. For example, one to three circuit board connectors 11c are provided for each circuit board main body 11a. Each circuit board connector 11c is fixed to the upper plate 11b, and is electrically connected to the circuit board main body 11a. Each of the above circuit board connectors 11c is connectable to an under base unit connector 34, which is included in the performance board unit 2b and is mentioned later on. In the present embodiment, the circuit board connector 11c is a male connector, while the under base unit connector 34 is a female connector. The circuit board connector 11c may be a female connector, and the under base unit connector 34 may be a male connector. By connecting the circuit board connector 11c to the under base unit connector 34, the circuit board unit 11 is electrically connected to the performance board unit 2b.

By inserting the circuit board main bodies 11a into the slots provided in the main body housing 10, each circuit board unit 11 is accommodated inside the main body housing 10. Each of the circuit board units 11 includes wiring so as to electrically connect to the control processing unit 12. In other words, each circuit board unit 11 is electrically connected to the control processing unit 12, inside the main body housing 10.

The control processing unit 12 is connected to each circuit board unit 11. The control processing unit 12 inputs a control signal to each circuit board unit 11 based on a test program or the like that is saved beforehand. The control processing unit 12 may process signals input from each circuit board unit 11. A battery may be accommodated in the main body housing 10. The control processing unit 12 may include a power unit to supply power from the battery to the various circuit board units 11 or the like.

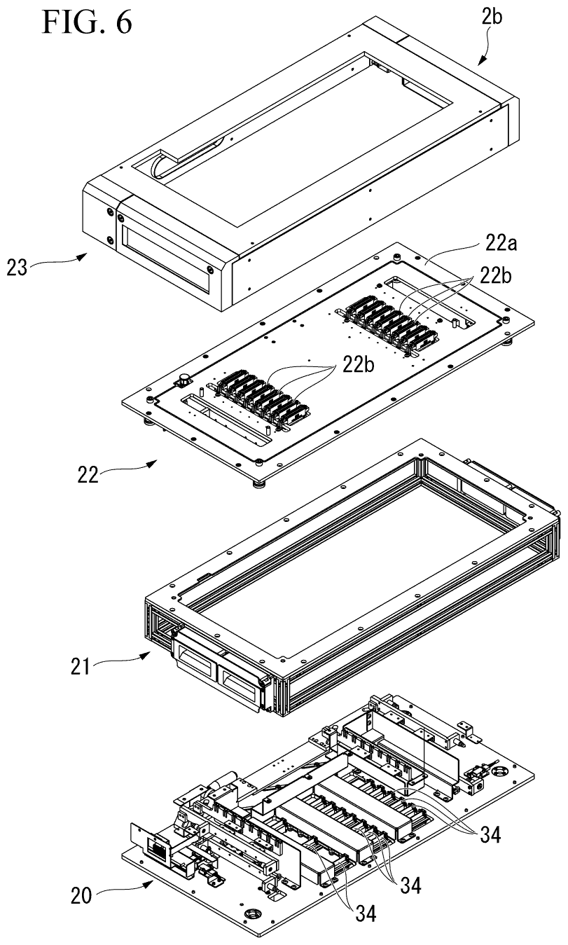

The performance board unit 2b is detachably attached to the main body 2a, and is fixed to the main body 2a via a locking mechanism that is not shown on the drawings. The performance board unit 2b is connected to the probe card 4 from above, and is electrically connectable to the wafer W via the probe card 4. FIG. 6 is a schematic exploded perspective view of the performance board unit 2b. As shown in FIG. 6, the performance board unit 2b includes an under base unit 20 (first unit), a frame unit 21, an upper base unit 22, and a cover unit 23.

The under base unit 20 is a unit that is located below more than the upper base unit 22, and includes the under base unit connector 34 and so on. By connecting the circuit board connector 11c to the under base unit connector 34, the under base unit 20 is electrically connected to the main body 2a. The under base unit 20 is explained in further detail later on.

The frame unit 21 is a frame member that is located between the under base unit 20 and the upper base unit 22, and forms an interval between the under base unit 20 and the upper base unit 22. For example, a flexible circuit board, which is not shown on the drawings, that connects the under base unit connector 34 to the upper base unit 22 to be mentioned later on is accommodated within the interval between the under base unit 20 and the upper base unit 22.

The upper base unit 22 includes an upper base plate 22a, and a plurality of upper base unit connectors 22b. The upper base plate 22a is a plate member having a front-rear surface which faces the top-bottom direction, and onto which the upper base unit connector 22b is fixed. The upper base unit 22 is fixed to the frame unit 21, and is supported by the frame unit 21. The upper base unit connector 22b is a connector that is electrically connected to the probe cards 4, and is connectable to each of the probe cards 4.

The cover unit 23 is a cover member that covers the performance board unit 2b, the under base unit 20, and the frame unit 21. As shown in FIG. 3 and so on, in a state where a top surface of the upper base unit 22 is exposed, the upper base unit connector 2b, the under base unit 20, and the frame unit 21 are covered.

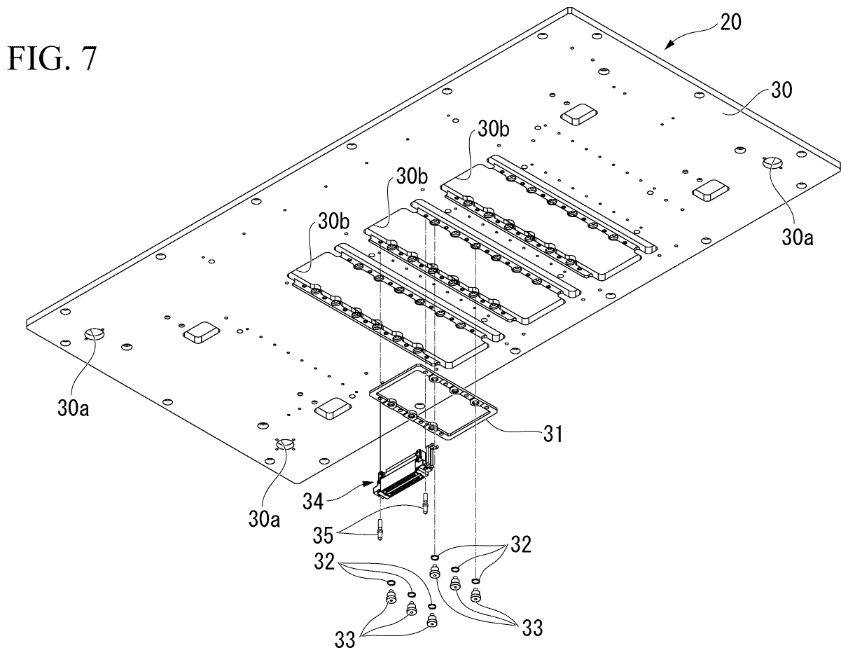

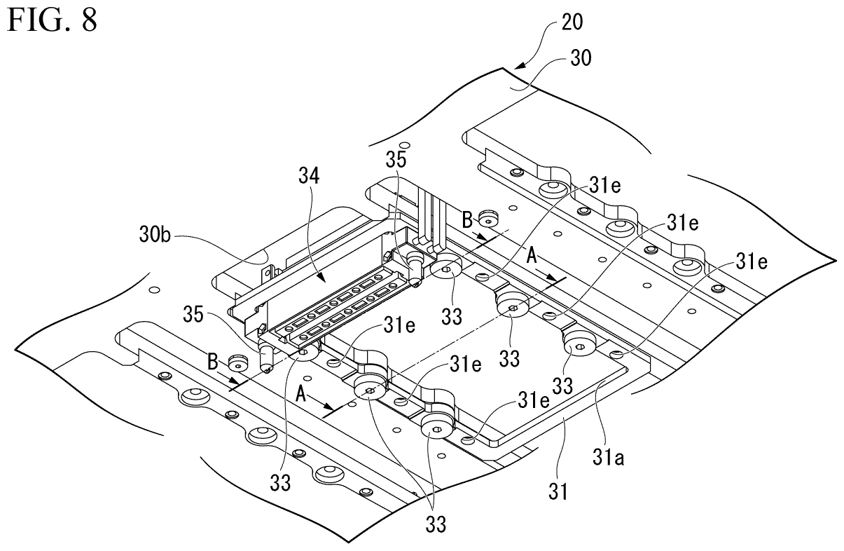

The under base unit 20 is explained in further detail. FIG. 7 is a schematic exploded perspective view of the under base 20. FIG. 8 is a schematic exploded perspective view of the under base unit 20 as seen diagonally from below. As shown in FIG. 7 and FIG. 8, the under base unit 20 includes an under base plate 30 (base plate), a floating plate 31 (moving part), a coil spring 32 (elastically deformable part), a stud bolt 33, the under base unit connector 34 (first connector), and a connector fixing pin 35 (positioning pin).

The under base plate 30 is a plate member that directly or indirectly supports the floating plate 31, the coil spring 32, the stud bolt 33, the under base unit connector 34, and the connector fixing pin 35. The under base plate 30 is disposed so that a front-rear surface thereof faces above. The under base plate 30 is formed as a rectangle when seen in planar view, having a positioning hole 30a into which the location pin 10a for the performance board unit is inserted provided on three out of four corners thereof. By inserting the location pins 10a for the performance board unit into the positioning holes 30a of the under base plate 30, the position of the performance board unit 2b with respect to the main body 2a in the horizontal direction is decided.

A plurality of through openings 30b which penetrate the under base unit connector 34 in the top-bottom direction are provided in the under base plate 30. For example, as shown in FIG. 7, a plurality of through openings 30b each of which is formed as a rectangle are provided in the under base plate 30. In the present embodiment, three through openings 30b are provided in the under base plate 30. A plurality of the under base unit connectors 34 aligned in a single direction are inserted through each of the through openings 30b. It is possible to change the number of the through openings 30b that are provided in the under base plate 30. The number of the under base unit connectors 34 that penetrate one through opening 30b for example, may differ for different through openings 30b.

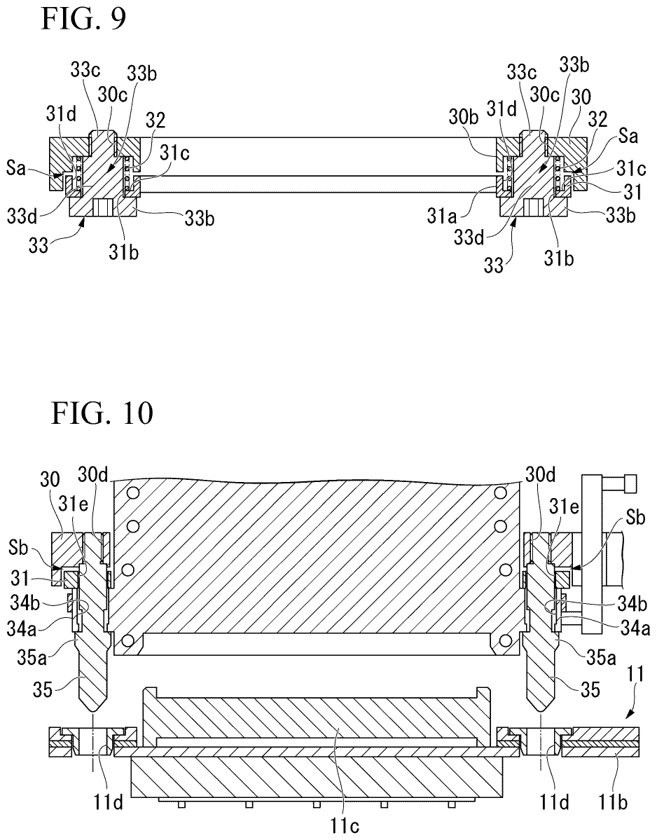

FIG. 9 is a cross-sectional view taken from A-A of FIG. 8. As shown in FIG. 9, a bolt hole 30c which is screw fastened to the stud bolt 33 is provided in the under base plate 30. A plurality of bolt holes 30c are provided on both sides of each through opening 30b, so as to sandwich said through opening 30b. The plurality of bolt holes 30c that are located on the same side with respect to the through opening 30b are disposed along the alignment direction of the plurality of under base unit connectors 34 which penetrate one through opening 30b.

The floating plate 31 is a frame member to which the plurality of under base unit connectors 34 contact from below. The floating plate 31 is connected to the under base plate 30 via the coil spring 32, and is a moving part which is movable in the top-bottom direction with respect to the under base plate 30. In the present embodiment, the under base unit connector 34 has the circuit board connector 11c relatively attached facing the top from the bottom. In other words, the floating plate 31 is movable on the under base plate 30 towards a mounting direction of the circuit board connector 11c with respect to the under base unit connector 34.

In the present embodiment, two floating plates 31 are provided with respect to one through opening 30b of the under base plate 30. In other words, in the present invention, the under base unit 20 includes six floating plates 31. However, in FIG. 7 and in FIG. 8, for the sake of explanation, only one out of the six floating plates 31 is shown, with the rest not being shown on the drawings.

A frame having a central opening 31a is formed in the floating plate 31. The central opening 31a is disposed so as to overlap with the through opening 30b of the under base plate 30 as seen from the top-bottom direction, and is an opening that penetrates the under base unit connector 34 in the top-bottom direction. In the present embodiment, the floating plate 31 is formed to be large enough so that it is possible for the under base unit connectors 34 to pass through central opening 31a.

The floating plate 31 includes a plurality of bolt openings 31b (openings) for bolts through which axes 33a, to be mentioned later on, of the stud bolts 33 are inserted through on both sides of the central opening 31a, so as to sandwich the central opening 31a inbetween. As an example, six stud bolts 33 are provided in the floating plate 31 in FIG. 7 and FIG. 8. As such, in the present embodiment, six bolt openings 31b are provided in the floating plate 31 shown in FIG. 7 and FIG. 8.

As show in the example of FIG. 9, a spring contact surface 31c which contacts the coil spring 32 from above is provided in the periphery of each bolt opening 31b in the floating plate 31. In the present embodiment, the above spring contact surfaces 31c are located below more than a top surface of the floating plate 31. A recess 31d that corresponds to each of the bolt opening 31b is provided on the floating plate 31. The bottom surface of the recess 31d is the spring contact surface 31c. Out of a bottom surface of the floating plate 31, the portion located in the rear side of the spring contact surface 31c is a head 33b, to be mentioned later on, of the stud bolt 33.

FIG. 10 is a cross-sectional view taken from B-B of FIG. 8. As shown in FIG. 10 for example, the floating plate 31 includes a plurality of pin insertion holes 31e each of which the connector fixing pin 35 is inserted, on each side of the central opening 31a, so as to sandwich the central opening 31a inbetween. It is possible to insert eight connector fixing pins 35 with respect to the floating plate 31 in the example of FIG. 7 and FIG. 8. Accordingly, in the present embodiment, eight pin insertion holes 31e are provided in the floating plate 31 shown in FIG. 7 and FIG. 8. Out of the bottom surface of the floating plate 31, the surface around the pin insertion hole 31e is a contact surface a protrusion 34a, to be mentioned later on, of the under base unit connector 34.

The coil spring 32 contacts the under base plate 30 from below, and a bottom end thereof is an elastically deformable part that contacts the floating plate 31 from above. In other words, the coil spring 32 is interposed between the under base plate 30 and the floating plate 31 so as to be sandwiched by the under base plate 30 and the floating plate 31 in the top-bottom direction. The coil spring 32 is formed as a cylinder into which the axis 33a of the stud bolt 33 is inserted. The coil spring 32 is elastically deformable so as to be able to compress in the top-bottom direction, and is able to press the floating plate 31 towards the top from below due to the restoring force thereof. As an example, six stud bolts 33 are provided in the floating plate 31 shown in FIG. 7 and FIG. 8. Therefore, in the present embodiment, six coil springs 32 are provided in the floating plate 31 shown in FIG. 7 and FIG. 8.

Each stud bolt 33 includes the axis 33a and the head 33b. As shown in FIG. 9 for example, the axis 33a includes a tip 33c that is screw fastened to the under base plate 30, and a body part 33d having a diameter larger than the tip 33c. The tip 33c is inserted into the bolt hole 30c of the under base plate 30 from below. The body part 33d is located between the tip 33c and the head 33b, and is a part that is inserted in the cylindrical coil spring 32. The diameter of the body part 33d is smaller than the head 33b.

The head 33b is connected to the axis 33a, and is connectable to the bottom surface of the floating plate 31 from below. It is possible for the head 33b to restrict top to bottom movement of the floating plate 31. As previously mentioned, a direction of mounting the circuit board connector 11c to the under base unit connector 34 is from top to bottom. In other words, the head 33b restricts movement of the floating plate 31 from top to bottom, which is the opposite of the mounting direction thereof.

In a case where the head 33b contacts the floating plate 31, the head 33b is disposed at a location (referred to as “interval above bolt location Sa”) that is formed in the interval between the floating plate 31 and the under base plate 30. In other words, the head 33b is disposed at a location where the floating plate 31 is movable (along a mounting direction of the circuit board connector 11c to the under base unit connector 34) from the bottom towards the top between the head 33b and the under base plate 30.

As an example, six stud bolts 33 are provided in the floating plate 31 shown in FIG. 7 and FIG. 8. However, it is possible to change the number of stud bolts 33 provided in one floating plate 31.

The under base unit connector 34 is a connector to which the circuit board connector 11c of the circuit board unit 11 is attached. Each of the under base unit connectors 34 is electrically connected to the upper base unit connector 22b of the upper base unit 22. By having the circuit board connector 11c inserted into the under base unit connector 34, the circuit board connector 11c and the upper base unit connector 22b are electrically connected.

The protrusion 34a is provided with respect to the bottom of the under base unit connector 34. The protrusion 34a is located below more than the floating plate 31, and contacts the bottom surface of the floating plate 31 from below. The protrusion through hole 34b through which the connector fixing pin 35 is inserted through is provided in the protrusion 34a. The protrusion 34a is provided so as to protrude to the outside of the main body of the under base unit connector 34, in the horizontal direction that is orthogonal to the alignment direction of the plurality of under base unit connectors 34 which penetrate the same through opening 30b.

Two connector fixing pins 35 are provided for every one under base unit connector 34. One of each connector fixing pin 35 is provided with respect to the protrusion 34a of the under base unit connector 34. The connector fixing pin 35 is inserted through each protrusion through hole 34b. The connector fixing pin 35 is also inserted through the pin insertion hole 31e of the floating plate 31. In other words, the protrusion through hole 34b and the pin insertion hole 31e are disposed so as to overlap in planar view, and the connector fixing pin 35 is inserted through both the overlapping protrusion through hole 34b and the pin insertion hole 31e. It is possible to move the connector fixing pin 35 that is inserted through the floating plate 31 and the under base unit connector 34 in the top-bottom direction.

As shown in FIG. 10, a flange 35a is provided on the connector fixing pin 35. The flange 35a is a part that protrudes towards the outside in the radial direction of the connector fixing pin 35. The flange 35a is located below the protrusion 34a of the under base unit connector 34, and contacts the protrusion 34a of the under base unit connector 34 from above.

The flange 35a is disposed on the interval formed between the floating plate 31 and the under base plate 30 (referred to as “interval above pin location Sb”), in a case where the flange 35a contacts the protrusion 34a of the under base unit connector 34 from above. In other words, the flange 35a is disposed at a location where the floating plate 31 and the under base unit connector 34 are movable towards the top from the bottom (along the mounting direction of the circuit board connector 11c to the under base unit connector 34), in the interval between the flange 35a and the under base plate 30. For example, a dimension of the interval above pin location Sb in the top-bottom direction is the same as a dimension of the interval above bolt location Sa in the top-bottom direction. The dimension of the interval above pin location Sb in the top-bottom direction may be smaller than the dimension of the interval above bolt location Sa in the top-bottom direction.

A top end of the connector fixing pin 35 is inserted through the thread hole 30d of the under base plate 30 from below, and is screw fastened to the under base plate 30. The bottom end of the connector fixing pin 35 is inserted through the insertion hole 11d provided on the circuit board unit 11 from above.

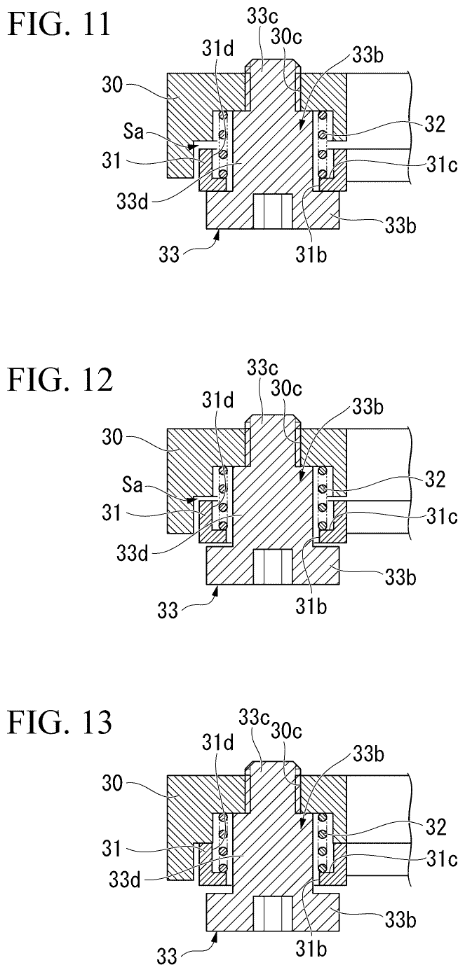

Next, a mounting operation of the performance board unit 2b to the main body 2a in inspection system 1 of the present embodiment is explained with reference to FIG. 11 through to FIG. 16.

FIG. 11 to FIG. 13 are schematic exploded cross-sectional views which show the stud bolt 33 of the under base unit 20. FIG. 11 shows a state where the floating plate 31 is at the lowest between the head 33b and the under base plate 30. The location of the floating plate 31 shown in FIG. 11 is referred to as the “lowest location”. FIG. 12 shows a state where the floating plate 31 is located on the middle in the interval between the head 33b and the under base plate 30. The location of the floating plate 31 in FIG. 12 referred to as a “middle location”. FIG. 13 shows a state where the floating plate 31 is at the highest between the head 33b and the under base plate 30. The location of the floating plate 31 in FIG. 11 is referred to as the “highest location”.

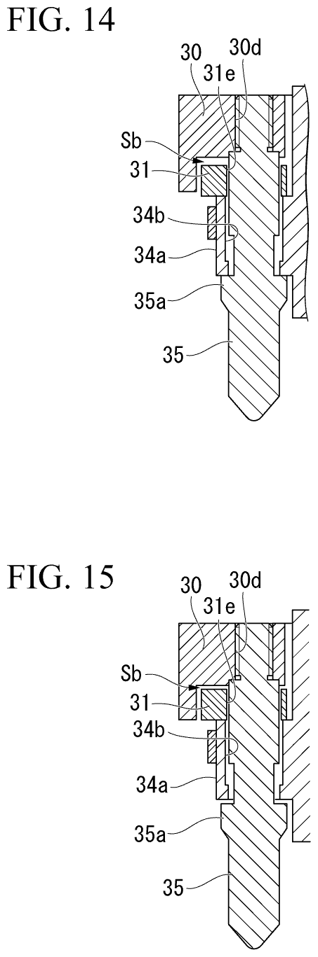

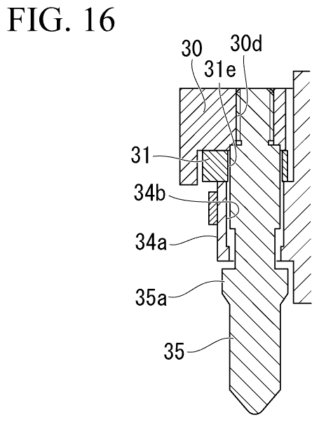

FIG. 14 to FIG. 16 are schematic exploded cross-sectional views that show the connector fixing pin 35 of the under base unit 20 in an embodiment of the present invention. FIG. 14 shows a state where the floating plate 31 is at the lowest between the flange 35a and the under base plate 30. The location of the floating plate 31 shown in FIG. 14 matches the lowest location shown in FIG. 11. FIG. 15 shows a state where the floating plate 31 is located on the middle between the flange 35a and the under base plate 30. The location of the floating plate 31 shown in FIG. 15 matches the middle location shown in FIG. 12. FIG. 16 shows a state where the floating plate 31 is at the highest between the flange 35a and the under base plate 30. The location of the floating plate 31 shown in FIG. 16 matches the highest location shown in FIG. 13.

In a state where the circuit board connector 11c is not attached to the under base unit connector 34, the floating plate 31 is located at the lowest location as shown in FIG. 11 and FIG. 14 due to for example, the pressing force of the coil spring 32, the weight of the floating plate 31 and the weight of the under base unit connector 34. At such time, dimensions of the interval above bolt location Sa shown in FIG. 11 and the interval above pin location Sb shown in FIG. 14 are at their largest.

Next, the performance board unit 2b is attached to the main body 2a. For example, in a state where the main body 2a is placed, the performance board unit 2b is brought down onto the top surface of the main body 2a, and the performance board unit 2b is fixed to the main body 2a by a locking mechanism not shown on the drawings.

The under base unit connector 34 is mounted to the circuit board connector 11c from above. In other words, the circuit board connector 11c is relatively mounted from the bottom to the top of the under base unit connector 34.

For example, there are cases where the a location of the circuit board connector 11c to the circuit board main body 11a is lower than originally designed, or where the attachment location of the circuit board unit 11 to the main body housing 10 is lower than originally designed exists.. In such cases, the floating plate 31 for example is connected to the circuit board connector 11c while at the lowest location.

On the other hand, in a case where the attachment location of the circuit board connector 11c to the circuit board main body 11a, or the attachment location of the circuit board unit 11to the main body housing 10 is within the range of the originally designed value, the floating plate 31 for example is in the middle location, as shown in FIG. 12 and FIG. 15. This is due to the fact that the under base unit connector 34 is lifted up by the circuit board connector 11c, and the coil spring 32 compresses by elastically deforming.

In a case where the attachment location of the circuit board connector 11c to the circuit board main body 11a, or the attachment location of the circuit board unit 11 to the main body housing 10 is higher than originally designed, as shown in FIG. 13 and FIG. 16, the floating plate 31 for example is at the highest location. This is due to the fact that the under base unit connector 34 is further lifted up by the circuit board connector 11c, further compressing the coil spring 32.

The tester 2 in the present embodiment as explained above includes the under base unit 20 and the circuit board unit 11. The under base unit 20 includes the under base unit connector 34. The circuit board unit 11 includes the circuit board connector 11c connected to the under base unit connector 34. The under base unit 20 includes the under base plate 30, the floating plate 31, and the coil spring 32. The floating plate 31 is in contact with the under base unit connector 34. It is possible to move the floating plate 31 with respect to the under base plate 30 in the mounting direction of the circuit board connector 11c to the under base unit connector 34. The coil spring 32 elastically deformable, and interposes between the under base plate 30 and the floating plate 31 in the attachment direction.

In the aforementioned tester 2 of the current embodiment, it is possible for the floating plate 31 to move in the top-bottom direction (mounting direction) with respect to the circuit board unit 11. In other words, as mentioned above, it is possible for the floating plate 31 to move between the different locations of the highest location, the middle location, and the lowest location or the like. Therefore, according to the tester 2 of the present embodiment, for example, in a case where the location of the circuit board connector 11c is lower than the design target value due to dimensional errors or the like, by having the floating plate 31 be at the lowest location, it is possible to have the circuit board connector 11c and the under base unit connector 34 more assuredly fit with one another. According to the tester 2 of the present embodiment, for example, in a case where the location of the circuit board connector 11c is higher than the design target value due to dimensional errors or the like, by having the floating plate 31 be at the highest location, it is possible to have the circuit board connector 11c and the under base unit connector 34 more assuredly fit with one another. For example, in a case where the location of the circuit board connector 11c is the target value of the design target value, by having the floating plate 31 be the middle location, it is possible to more assuredly fit the circuit board connector 11c to the under base unit connector 34. Therefore, according to the tester 2 of the current embodiment, it is possible to more assuredly have connectors (the circuit board connector 11c and the under base unit connector 34 in the present embodiment) connect to one another in the tester 2 which includes a plurality of units that are connected using connectors.

In the tester 2 of the present embodiment, the under base unit 20 includes a stud bolt 33 having the axis 33a fixed to the under base plate 30. For example, the bolt opening 31b through which the axis 33a penetrates is provided in the floating plate 31. As another example, the coil spring 32 is interposed between the under base plate 30 and the floating plate 31 formed as a cylinder through which the axis 33a is inserted.

According to the tester 2 of the present embodiment, since the axis 33a of the stud bolt 33 penetrates the coil spring 32, it is possible to prevent the coil spring 32 from coming off of the stud bolt 33, and it is possible to more assuredly conduct positioning of the coil spring 32.

The stud bolt 33 in the tester 2 of the present embodiment includes the head 33b which is connected to the axis 33a. The head 33b restricts movement of the floating plate 31 in a direction that is opposite to the mounting direction. The head 33b is disposed at a location that is movable along the mounting direction of the floating plate 31 between the head 33b and the under base plate 30.

According to the tester 2 of the present embodiment, the movable distance of the floating plate 31 is restricted by the location of the head 33b. Therefore, when adjusting a location of the head 33b by changing the amount the stud bolt 33 is fastened to the under base plate 30, it is possible to easily adjust the movable distance of the floating plate 31 in the top-bottom direction.

The under base unit 20 in the tester 2 of the present embodiment includes the connector fixing pin 35 which is insertable into the circuit board unit 11. The coil spring 32 is disposed at a location that is different than the location of the connector fixing pin 35 when seen from the mounting direction.

According to the tester 2 in the present embodiment, there is no need to set the coil spring 32 around the connector fixing pin 35. Therefore, according to the tester 2 of the present embodiment, it is possible to place the coil spring 32 regardless of the shape of the connector fixing pin 35.

In the tester 2 of the present embodiment, a plurality of coil springs 32 are provided for one floating plate 31. According to the tester 2 of the present embodiment, it is possible to distribute the load that is received by the floating plate 31 among the plurality of the coil springs 32, reducing the load on each individual coil spring 32.

In the tester 2 of the present embodiment, the plurality of under base unit connectors 34 are in contact with one floating plate 31. In such tester 2 of the present embodiment, a single floating plate 31 is provided for the plurality of under base unit connectors 34. For example, it is possible to provide one floating plate 31 for each one of the plurality of under base unit connectors 34. However, as in the present embodiment, by providing a single floating plate 31 for the plurality of under base unit connectors 34, it is possible to simplify a structure of the under base unit 20.

The inspection system 1 of the present embodiment includes the tester 2 and the prober 3. The prober 3 connects the wafer W having the semiconductor integrated circuit provided thereon and the tester 2.

According to the inspection system 1 of the present embodiment, since the tester 2 is included, it is possible to more assuredly connect the connectors (the circuit board connector 11c and the under base unit connector 34 in the present embodiment) to one another.

Although a preferable embodiment of the present invention is explained above, the embodiment serves as an example, and the present invention should not be construed as being limited to the embodiment herein. Additions, omissions, exchanging of components or other changes may be made so long as they are within the technical scope of the present invention. Therefore, the present invention is not limited to the aforementioned embodiment, but rather by the technical scope of the present invention.

For example, in the aforementioned embodiments, an example where an inspection system that includes the prover 3 as the test object transport device is explained. However, the present invention is not limited thereto. For example, it is possible to apply a handler as the test object transport device included in the inspection system of the present invention. When applying a handler as the test object transport device included in the inspection system of the present invention, the tester 2 is moved with respect to the handler, and the tester 2 is connected to the wafer via the probe card.

The test object is not limited to a wafer. For example, the test object may be a packaged device. In such case, the tester 2 is connected to the device via a test socket.

In the aforementioned embodiment, a case of the coil spring 32 configuring the elastically deformable body is explained. However, the present invention is not limited thereto. For example, the elastically deformable body may configured from a spring other than a coil spring, or the elastically deformable body may be configured from rubber.

In the aforementioned embodiment, a configuration where the under base unit 20 is the first unit, and the circuit board unit 11 is the second unit is explained. However, the present invention is not limited thereto. In other words, in a case where the tester 2 configures a plurality of units, it is possible to optionally set any unit to be the first unit, and any other unit to be the second unit.

Although embodiments of the present invention have been described above in detail with reference to the drawings, specific configurations are not limited to the embodiments and other designs and the like may also be included without departing from the objective and scope of the present invention.

What is claimed is:

1. A semiconductor testing device comprising:
a first unit that includes a first connector; and
a second unit that includes a second connector which is connectable to the first connector; wherein
the first unit includes
a base,
a moving part that contacts the first connector, and is movable relative to the base in a mounting direction of the second connector with respect to the first connector, and
an elastically deformable part that is elastically deformable, and interposes between the base and the moving part in the mounting direction.

2. The semiconductor testing device according to claim 1, wherein
the first unit further comprises a stud bolt that includes an axis which is fixed to the base,
the moving part includes an opening through which the axis penetrates, and
the elastically deformable part is formed as a cylinder into which the axis is inserted, and
the elastically deformable part interposes between the base and the movable part.

3. The semiconductor testing device according to claim 2, wherein
the stud bolt includes a head connected to the axis, and
the head is capable of restricting movement of the moving part in a direction opposite to the mounting direction, and is disposed at a location where the moving part is movable along the mounting direction between the head and the base.

4. The semiconductor testing device according to claim 1, wherein
the first unit further includes a location pin that is insertable into the second unit, and
the elastically deformable part is disposed at a location that is different from a location of the location pin, when seen from the mounting direction.

5. The semiconductor testing device according to claim 1, wherein
a plurality of the elastically deformable part is provided for the moving part.

6. The semiconductor testing device according to claim 1, wherein
a plurality of the first connectors are in contact with the moving part.

7. An inspection system comprising:
the semiconductor testing device according to claim 1; and
a test object transport device that transports a test object which has a semiconductor integrated circuit provided thereon, and connects the test object to the semiconductor testing device.
